(19) United States
(12) Patent Application Publication
(10) Pub. No.: US 2024/0096726 A1
(43) Pub. Date: Mar. 21, 2024

(54) NITRIDE-BASED SEMICONDUCTOR DEVICE AND METHOD FOR OPERATING THE SAME

(71) Applicant: INNOSCIENCE (SUZHOU) SEMICONDUCTOR CO., LTD., Suzhou City (CN)

(72) Inventors: Haohua MA, Suzhou City (CN); Hehong WU, Suzhou City (CN); Sichao LI, Suzhou City (CN); Hui YAN, Suzhou City (CN)

(21) Appl. No.: 17/767,430

(22) PCT Filed: Dec. 31, 2021
(86) PCT No.: PCT/CN2021/143728

§ 371 Date: Apr. 7, 2022

(51) Int. Cl. H01L 23/34; H01L 23/31; H01L 27/095; H01L 29/20; H01L 29/40; H01L 29/417; H01L 29/778; H03K 17/56

(52) U.S. Cl. CPC H01L 23/34; H01L 23/3171; H01L 23/3192; H01L 27/095; H01L 29/2003; H01L 29/402; H01L 29/41758; H01L 29/7786; H03K 17/56

(57) ABSTRACT

A nitride-based semiconductor device includes a first nitride-based semiconductor layer, a second nitride-based semiconductor layer, a first nitride-based transistor, a second nitride-based transistor, and a thermal resistor. The first nitride-based transistor is disposed over the second nitride-based semiconductor layer and applies the 2DEG region as an own channel. The second nitride-based transistor is disposed over the second nitride-based semiconductor layer and applying the 2DEG region as an own channel. The temperature sensor is disposed over the second nitride-based semiconductor layer and between first and second nitride-based transistors. The temperature sensor is in a strip shape and at least turns twice in a region between first and second nitride-based transistors.

### FIELD OF THE DISCLOSURE

The present disclosure generally relates to a nitride-based semiconductor device. More specifically, the present disclosure relates to a nitride-based semiconductor device integrated with a thermal resistor/temperature sensor.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

With the development trend of miniaturization and high power, GaN-based devices generate amount of heat during its operation period. The influence of self-heating effect on device performance and reliability has been becoming more serious. The junction temperature of the device is an important factor/parameter to evaluate the performance and reliability of the device. Therefore, there is a need to accurately measure the junction temperature thereof.

### SUMMARY OF THE DISCLOSURE

In accordance with one aspect of the present disclosure, a semiconductor device is provided. A nitride-based semiconductor device includes a first nitride-based semiconductor layer, a second nitride-based semiconductor layer, a first nitride-based transistor, a second nitride-based transistor, and a thermal resistor. The second nitride-based semiconductor layer is disposed on the first nitride-based semiconductor layer and has a bandgap greater than a bandgap of the first nitride-based semiconductor layer, so as to generate a two-dimensional electron gas (2DEG) region adjacent to heterojunction between the first and second nitride-based semiconductor layers. The first nitride-based transistor is disposed over the second nitride-based semiconductor layer and applies the 2DEG region as an own channel. The second nitride-based transistor is disposed over the second nitride-based semiconductor layer and applying the 2DEG region as an own channel. The temperature sensor is disposed over the second nitride-based semiconductor layer and between first and second nitride-based transistors. The temperature sensor is in a strip shape and at least turns twice in a region between first and second nitride-based transistors.

In accordance with one aspect of the present disclosure, a semiconductor device is provided. A nitride-based semiconductor device includes a first nitride-based semiconductor layer, a second nitride-based semiconductor layer, a nitride-based transistor, and a thermal resistor. The second nitride-based semiconductor layer is disposed on the first nitride-based semiconductor layer and has a bandgap greater than a bandgap of the first nitride-based semiconductor layer, so as to generate a two-dimensional electron gas (2DEG) region adjacent to heterojunction between the first and second nitride-based semiconductor layers. The nitride-based transistor is disposed over the second nitride-based semiconductor layer and applies the 2DEG region as a channel. The temperature sensor is disposed over the second nitride-based semiconductor layer and around the nitride-based transistor. The temperature sensor has at least one conductive pad spaced apart from the nitride-based transistor.

In accordance with one aspect of the present disclosure, a method for operating a nitride-based semiconductor device is provided. The method includes steps as follows. A nitride-based transistor is switched on in the nitride-based semiconductor device by inputting a first current into the nitride-based transistor. A second current is inputted into a temperature sensor in the nitride-based semiconductor device. Variety in a value of a first voltage of the temperature sensor during a time period of inputting the second current.

By the above configuration, in embodiments of the present disclosure, the temperature sensor is located between the first and second nitride-based transistor, such that the temperature sensor can be thermally coupled to the first and second nitride-based transistors. As such, the temperature sensor can sense a junction temperature of the semiconductor device precisely and immediately. The temperature sensor can output a temperature signal according to the junction temperature, and the accuracy of junction temperature measurement can be improved.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a top view of a semiconductor device according to some embodiments of the present disclosure;

FIG. 1B is a vertical cross-sectional view of the semiconductor device along the line I-I′ in the FIG. 1A;

FIG. 1C is an enlarged schematic top view of a configuration of a transistor and a temperature sensor in FIG. 1A;

FIG. 2A is an equivalent circuit diagram of the semiconductor device of FIGS. 1A and 1B and a voltage detecting circuit according to some embodiments of the present disclosure;

FIG. 2B shows different steps of a method for operating a nitride-based semiconductor device according to some embodiments of the present disclosure;

FIG. 3 is a vertical view of a semiconductor device according to some embodiments of the present disclosure; and

FIG. 4 is a top view of an enlarged region of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

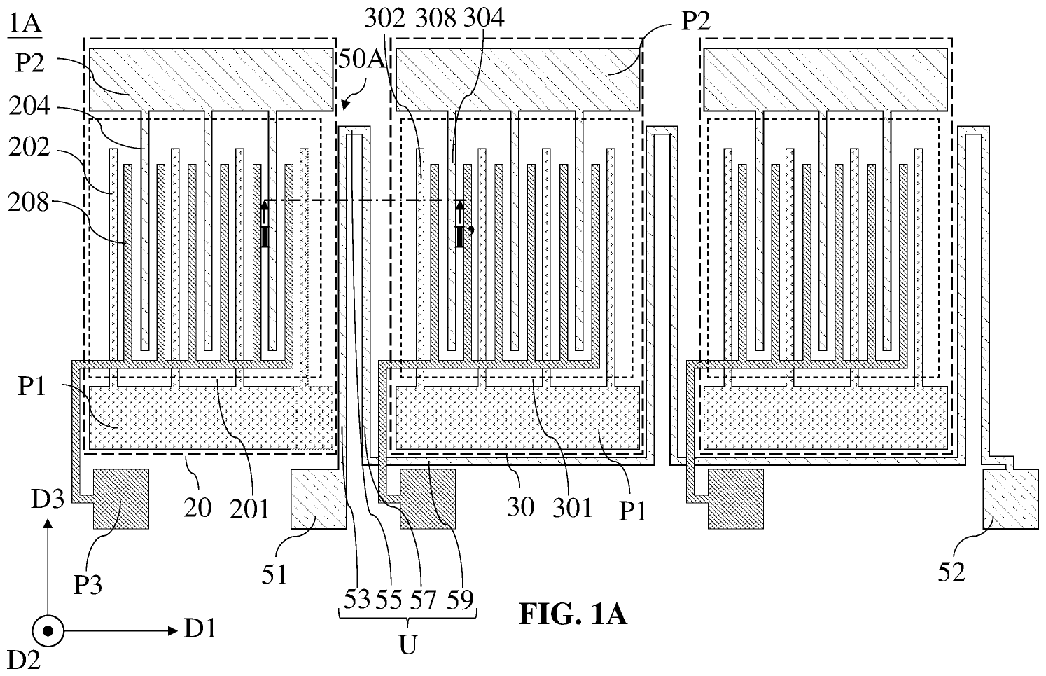

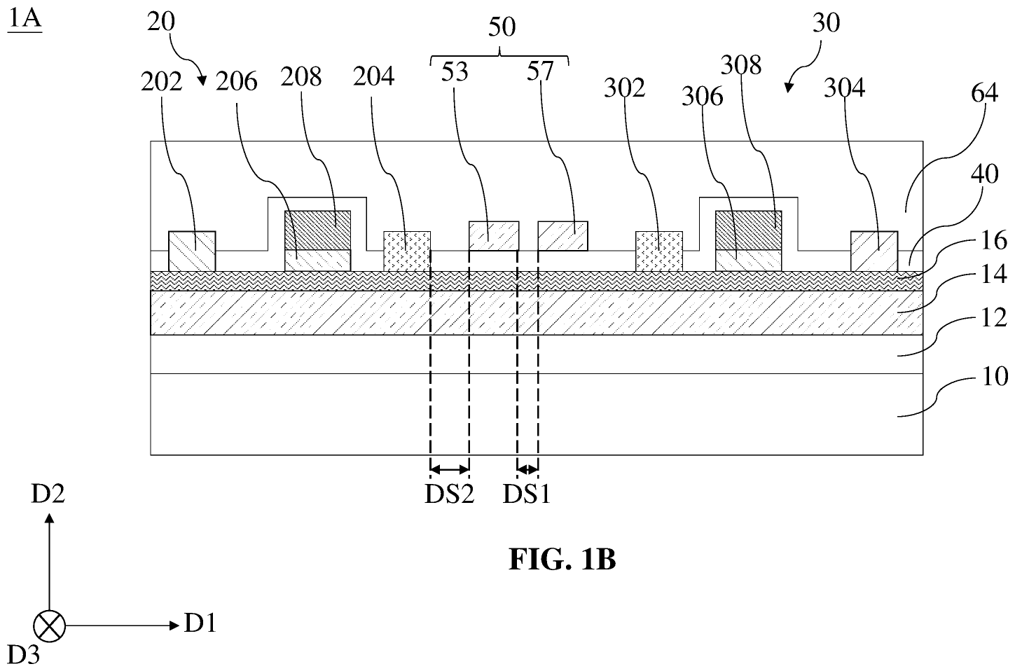

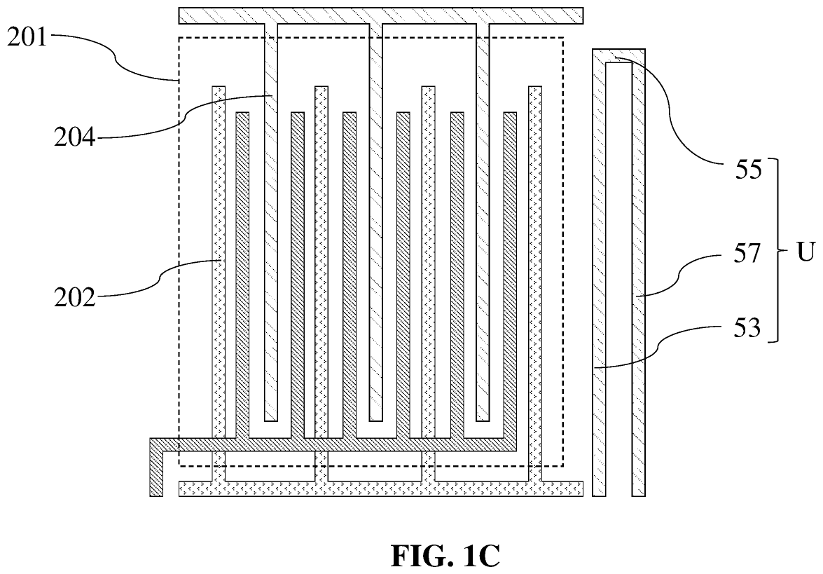

FIG. 1A is a top view of a semiconductor device 1A according to some embodiments of the present disclosure. FIG. 1B is a vertical cross-sectional view of the semiconductor device 1A along the line I-I′ in the FIG. 1A. The directions D1, D2 and D3 are labeled in the FIGS. 1A and 1B, in which the directions D1, D2 and D3 are different from each other. The directions D1 to D3 are perpendicular to each other.

The semiconductor device 1A includes a substrate 10, a buffer layer 12, nitride-based semiconductor layers 14, 16, nitride-based transistors 20, 30, a passivation layer 40, a temperature sensor 50A, and a passivation layer 64.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The buffer layer 12 can be disposed on/over/above the substrate 10. The buffer layer 12 can be disposed between the substrate 10 and the nitride-based semiconductor layer 14. The buffer layer 12 can be configured to reduce lattice and thermal mismatches between the substrate 10 and the nitride-based semiconductor layer 14, thereby curing defects due to the mismatches/difference. The buffer layer 12 may include a III-V compound. The III-V compound can include, for example but are not limited to, aluminum, gallium, indium, nitrogen, or combinations thereof. Accordingly, the exemplary materials of the buffer layer 12 can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and the buffer layer 12. The nucleation layer can be configured to provide a transition to accommodate a mismatch/difference between the substrate 10 and a III-nitride layer of the buffer layer 12. The exemplary material of the nucleation layer can include, for example but is not limited to AlN or any of its alloys.

The nitride-based semiconductor layer 14 can be disposed on/over/above the substrate 10. The nitride-based semiconductor layer 16 can be disposed on/over/above the nitride-based semiconductor layer 14. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, AlₓGa₍₁₋ₓ₎N, where x≤1. The exemplary materials of the nitride-based semiconductor layer 16 can include, for example but are not limited to, nitrides or group III-V compounds, such as GaN, AlN, InN, InₓAl_{y}Ga_{(1-x-y)}N where x+y≤1, Al_{y}Ga_{(1-y)}N, where y≤1.

The exemplary materials of the nitride-based semiconductor layers 14 and 16 are selected such that the nitride-based semiconductor layer 16 has a bandgap (i.e., forbidden band width) greater/higher than a bandgap of the nitride-based semiconductor layer 14, which causes electron affinities thereof different from each other and forms a heterojunction therebetween. For example, when the nitride-based semiconductor layer 16 is an AlGaN layer having bandgap of approximately 4.0 eV, the nitride-based semiconductor layer 14 can be selected as an undoped GaN layer having a bandgap of approximately 3.4 eV. As such, the nitride-based semiconductor layers 14 and 16 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The nitride-based transistor 20 is disposed on/over/above the nitride-based semiconductor layers 14 and 16. The nitride-based transistor 20 includes electrodes 202, 204, doped nitride-based semiconductor layers 206, gate electrodes 208, and pads P1, P2, P3. The nitride-based transistor 30 includes electrodes 302, 304, doped nitride-based semiconductor layers 306, gate electrodes 308, and pads P1, P2, P3. The configuration of the transistor 20 will be fully described as follows. The configuration of the nitride-based transistor 20 can be applied to the nitride-based transistor 30. It should be noted that only three nitride-based transistors are shown in FIG. 1A. However, in other embodiments, the semiconductor device 1A can have more than three nitride-based transistors or only two nitride-based transistors. The disclosure is not limited thereto.

The electrodes 202 and 204 can be disposed on/over/above the nitride-based semiconductor layer 16. The electrodes 202 and 204 are directly in contact with the nitride-based semiconductor layer 16. Each of the electrodes 202/204 can be a stripe shape, and extends along the direction D3 (see FIG. 1A). The electrodes 202 are extended from the pad P1, and the electrodes 204 are extended from the pad P2. In some embodiments, the electrode 202 can serve as a source electrode, and the pad P1 can serve as a source pad. In some embodiments, the electrode 202 can serve as a drain electrode, and the pad P1 can serve as a drain pad. In some embodiments, the electrode 204 can serve as a source electrode, and the pad P2 can serve as a source pad. In some embodiments, the electrode 204 can serve as a drain electrode, and the pad P2 can serve as a drain pad. The role of the electrodes 202 and 204 (or the pads P1 and P2) depends on the device design.

In some embodiments, the electrodes 202, 204, and the pads P1 and P2 can include, for example but are not limited to, metals, alloys, doped semiconductor materials (such as doped crystalline silicon), compounds such as silicides and nitrides, other conductor materials, or combinations thereof. The exemplary materials of the electrodes 202, 204, and the pads P1, P2 can include, for example but are not limited to, Ti, AlSi, TiN, or combinations thereof.

Each of the electrodes 202, 204, and the pads P1, P2 may be a single layer, or plural layers of the same or different composition. The electrodes 202, 204 can form ohmic contacts with the nitride-based semiconductor layer 16. Furthermore, the ohmic contacts can be achieved by applying Ti, Al, or other suitable materials to the electrodes 202, 204. In some embodiments, each of the electrodes 202, 204 is formed by at least one conformal layer and a conductive filling. The conformal layer can wrap the conductive filling. The exemplary materials of the conformal layer can include, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

Each of the doped nitride-based semiconductor layers 206 is disposed on/over/above the nitride-based semiconductor layer 16. Each of the doped nitride-based semiconductor layers 206 is in contact with the nitride-based semiconductor layer 16. Each of the gate electrodes 208 is disposed on/over/above the doped nitride-based semiconductor layer 206 and the nitride-based semiconductor layer 16. Each of the gate electrodes 208 is in contact with the doped nitride-based semiconductor layer 206. Each of the doped nitride-based semiconductor layer 206 is disposed between the gate electrode 208 and the nitride-based semiconductor layer 16. The gate electrodes 208 are extended from the pad P3, and the pad P3 can serve as a gate pad. Each of the gate electrodes 208 extend along the direction D3. The pad P3 and the conductive pad 51 of the temperature sensor 50 are located at the same side of the pad P1.

The width of the gate electrode 208 can be the same as that of the doped nitride-based semiconductor layer 206. In some embodiments, a width of the doped nitride-based semiconductor layer 206 is greater than that of the gate electrode 208. The profiles of the doped nitride-based semiconductor layer 206 and the gate electrode 208 are the same, for example, both of them are rectangular profiles. In other embodiments, the profiles of the doped nitride-based semiconductor layer 206 and the gate electrode 208 can be different from each other. For example, the profile of the doped nitride-based semiconductor layer 206 can be a trapezoid profile, the profile of the gate electrode 208 can be a rectangular profile.

In the exemplary illustration of FIG. 1B, the semiconductor device 1A is an enhancement mode device, which is in a normally-off state when the gate electrodes 208 are at approximately zero bias. Specifically, the doped nitride-based semiconductor layers 206 may create at least one p-n junction with the nitride-based semiconductor layer 16 to deplete the 2DEG region, such that zones of the 2DEG region corresponding to positions below the corresponding the gate electrodes 208 have different characteristics (e.g., different electron concentrations) than the rest of the 2DEG region and thus is blocked.

Due to such mechanism, the semiconductor device 1A has a normally-off characteristic. In other words, when no voltage is applied to the gate electrodes 208 or a voltage applied to the gate electrodes 208 is less than a threshold voltage (i.e., a minimum voltage required to form an inversion layer below the gate electrodes 208), the zones of the 2DEG region below the gate electrodes 208 are kept blocked, and thus no current flows therethrough.

In some embodiments, the doped nitride-based semiconductor layers 206 can be omitted, such that the semiconductor device 1A is a depletion-mode device, which means the semiconductor device 1A in a normally-on state at zero gate-source voltage.

The doped nitride-based semiconductor layers 206 can be a p-type doped III-V semiconductor layer. The exemplary materials of the doped nitride-based semiconductor layers 206 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Zn, Cd, and Mg. In some embodiments, the nitride-based semiconductor layer 16 includes undoped GaN and the nitride-based semiconductor layer 14 includes AlGaN, and the doped nitride-based semiconductor layers 206 are p-type GaN layers which can bend the underlying band structure upwards and to deplete the corresponding zones of the 2DEG region, so as to place the semiconductor device 1A into an off-state condition.

The nitride-based transistor 20 applies the 2DEG region as an own channel. The nitride-based transistor 30 applies the 2DEG region as an own channel. That is to say, the nitride-based transistors 20 and 30 share the same 2DEG region.

The exemplary materials of the gate electrode 208 and the pad P3 may include metals or metal compounds. Each of the gate electrodes 208 and the pad P3 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The passivation layer 40 is disposed on/over/above the nitride-based semiconductor layer 14. The electrodes 202, 204, 302, 306 of the nitride-based transistors 20 and 30 penetrate the passivation layer 40, so as to make contacts with the nitride-based semiconductor layer 14. The material of the passivation layer 40 can include, for example but are not limited to, dielectric materials. For example, the passivation layer 40 can include, for example but are not limited to, SiNₓ, SiOₓ, Si₃N₄, SiON, SiC, SiBN, SiCBN, oxides, nitrides, plasma enhanced oxide (PEOX), or combinations thereof. In some embodiments, the passivation layer 40 can be a multi-layered structure, such as a composite dielectric layer of Al₂O₃/SiN, Al₂O₃/SiO₂, AlN/SiN, AlN/SiO₂, or combinations thereof.

For evaluating the performance and reliability of the device, many ways have been proposed to measure junction temperature thereof. For example, a tested device is connected to a test voltage source and a test current source in parallel, and the test voltage source and the test current source are controlled by two switches, respectively, named as a first switch and a second switch.

First, the first switch is turned on and the second switch is turned off, such that a test voltage can be applied to the tested device, and thus the tested device is to be heated. Then, the first switch is turned off and the second switch is turned on, such that a tested current can be applied to the tested device. During a time period of applying the tested current, voltage across two ends of the tested device is captured by the voltage capturing circuit, and thus the voltage characteristic curves can be obtained. Finally, the junction temperature of the tested device is calculated according to the obtained voltage characteristic curves. Nevertheless, in fact, during the switching period of the first and second switches, the actual junction temperature would decrease, so that the junction temperature calculated in this way has an obvious error due to time delay.

Another way is to measure temperature of different positions of an outer shell of a tested device by using a thermal couple to be in contact therewith, and then the junction temperature of the tested device is estimated by the shell temperature of these contact positions with the assistance of the software. However, the junction temperature estimated by such way is inaccurate due to variation of the contact positions.

At least to avoid the afore-mentioned issues, the present disclosure is to provide a novel temperature-detected structure for the nitride-based semiconductor devices.

Referring to FIGS. 1A and 1B, the temperature sensor 50A is disposed on/over/above the nitride-based semiconductor layer 16 and the passivation layer 40. The temperature sensor 50A is in contact with the passivation layer 40. The temperature sensor 50A is located between the nitride-based transistors 20 and 30. The temperature sensor 50 is around periphery regions of the nitride-based transistors 20, 30.

To be more specific, FIG. 1C is an enlarged schematic top view of a configuration of a transistor 20 and a temperature sensor 50A in FIG. 1A. As shown in FIG. 1A and FIG. 1C, the temperature sensor 50A includes a pair of the conductive pads 51, 52, and a plurality of temperature sensor units U. Each of the temperature sensor units U includes a pair of extending portions 53, 57 and connecting portions 55, 59. Each of the extending portions 53, 57 extends along the direction D3. Each of the extending portions 53 and 57 extend along a length greater than a length of each of the electrodes 202 and 204. Each of the connecting portions 55, 59 extends along the direction D1, that is to say, the extending portions 53, 57 of the temperature sensor 50, the electrodes 202, 204, and the gate electrodes 208 extend along the same direction D1. The extending portions 53 and 57 are parallel with each other, and the extending portions 53 and 57 are adjacent to the nitride-based transistors 20 and 30. The connecting portions 55 and 59 are parallel with each other. The extending portions 53 and 57 are located between the electrodes 204 and 302. In the temperature sensor unit U, the connecting portion 55 connects one of the extending portions 53 to another one of the extending portions 57. In two adjacent temperature sensor units U, the connecting portion 59 connects the extending portion 57 of one of the temperature sensor units U and the extending portion 53 of the another one of the temperature sensor units U.

Due to above configuration, at least a part of the temperature sensor 50A can be in a strip shape and at least turns twice in a region between two of the adjacent nitride-based transistors 20 and 30. The temperature sensor 50 is around periphery regions of the nitride-based transistors 20 and 30. The pair of conductive pads 51 and 52 connected to two ends of the temperature sensor 50A, respectively.

Each of the nitride-based transistors 20 and 30 has an active region 201/301. The conductive pads 50 and 52 viewed along the direction D2 (i.e., a direction normal to the nitride-based semiconductor layer 14) are out of the active regions 201 and 301 in a top view (see FIG. 1B). The conductive pads 51 and 52 are spaced apart from the nitride-based transistors 20 and 30. The pad P1 is located between the conductive pad 51 and the pad P2. The temperature sensor 50A viewed along the direction D2 is out of the active regions 201 and 301 in a top view (see FIG. 1B).

The exemplary materials of the temperature sensor 50A has a positive temperature coefficient (PTC), which means that the materials that experience an increase in electrical resistance when their temperature is raised. The exemplary materials of the temperature sensor 50A can include, for example but are not limited to, metal or metal compound. In some embodiments, the exemplary materials of the temperature sensor 50A can include Al or TiN. In some embodiments, the temperature sensor 50A can be a thermal resistor.

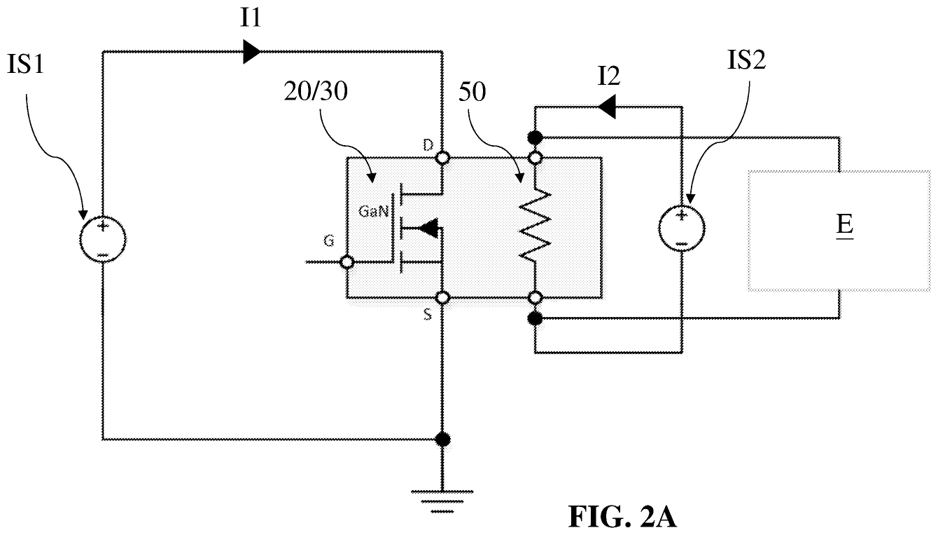

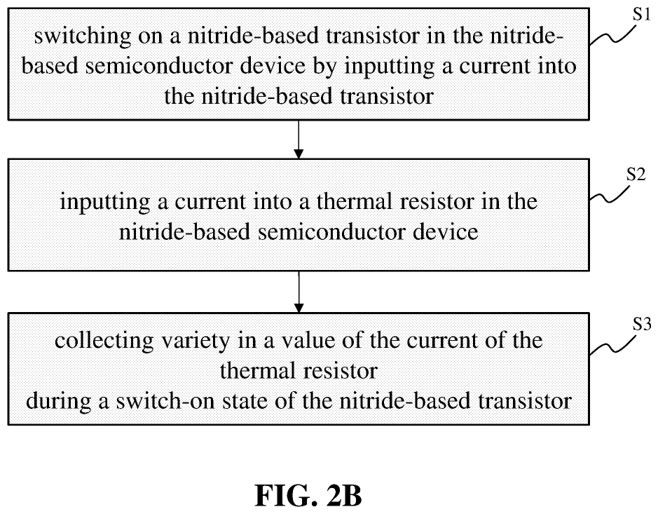

FIG. 2A is an equivalent circuit diagram of the semiconductor device 1A of FIGS. 1A-1C and a voltage detecting circuit according to some embodiments of the present disclosure. FIG. 2B shows different steps of a method for operating a nitride-based semiconductor device 1A according to some embodiments of the present disclosure. The steps of measuring the junction temperature of the semiconductor device 1A will be described in detail in following paragraphs in conjunction with FIGS. 2A and 2B.

Referring to FIG. 2A, a positive and a negative poles of a current supply IS1 are electrically connected to a drain and a source electrodes of the nitride-based transistor 20/30, respectively. On the other hand, a current supply source IS2 is electrically connected to the temperature sensor 50A, in which the current supply source IS2 includes a constant current source. A voltage detecting circuit E is connected to two ends of the temperature sensor 50A via the conductive pads (the conductive pads 51 and 52 as afore described) in parallel with the current supply source IS2, so as to detect a voltage across two ends of the temperature sensor 50A.

Referring to FIGS. 2A and 2B, in the step S1, the current supply IS1 can input a current I1 into the nitride-based transistor 20/30 to switch on the nitride-based transistor 20/30 in the nitride-based semiconductor device 1A for a time period Tₒₙ, such that the nitride-based transistor 20/30 can be heated.

In the step S2, the current supply IS2 can input a current I2 into a temperature sensor 50A in the nitride-based semiconductor device 1A, in which the current I2 is a constant current (i.e., the intensity of the current I2 is constant). In some embodiments, a value of the current I1 is much greater than that of the current I2. The reason is to make the nitride-based transistor 20/30 heated effectively.

In the step S3, the voltage detecting circuit E detects a voltage of the temperature sensor 50A during a time period of applying the current I2, so as to collect variety in a value of the voltage of the temperature sensor 50. In some embodiments, the current supply source IS1 can increase a value of the current I1, and the voltage detecting circuit E can continuously collect variety in the value of the voltage of the temperature sensor 50A in response to the increase of the value of the current I1. In some embodiments, the current supply source IS1 can decrease a value of the current I1, and the voltage detecting circuit E can continuously collect variety in the value of the voltage of the temperature sensor 50A in response to the decrease of the value of the current I1. After that, the operation of the current supply sources IS1 and IS2 are terminated.

In other embodiments, the operation of the current supply source IS1 can be terminated first, and then the operation of the current supply source IS2 can still provide the current I2 to the temperature sensor 50A to detect the junction temperature of the nitride-based transistors 20, 30.

As such, the voltage detecting circuit E can record the variation of the current I1 and the voltage of the temperature sensor 50A, and output a plurality of curves to a processor (not shown). Then, the processor can calculate/estimate the junction temperature of the nitride-based transistor 20/30 according to the outputted curves and a temperature coefficient of the temperature sensor 50A.

Based on the above, the nitride-based transistors 20, 30 and the temperature sensor 50 are packaged such that the nitride-based transistor 20 and 30 are adjacent to the temperature sensor 50A. In this regard, each of the temperature sensor units U of the temperature sensor 50A is disposed/embedded in a region between any two of the adjacent nitride-based transistors 20 and 30 and the temperature sensor 50A. Therefore, the location of the temperature sensor 50A is adjacent to the junction of the nitride-based transistors 20 and 30, and thus the temperature sensor 50A can be well thermally coupled to the nitride-based transistors 20 and 30.

Since the material of the temperature sensor 50A is highly sensitive to the temperature, the temperature sensor 50A can rapidly respond to the temperature variation near the junction of the nitride-based transistors 20, 30. The heat generated at the junction of the nitride-based transistors 20 and 30 during the operation period thereof can rapidly transmit to the conductive pads 51 and 52 for the voltage detecting circuit E to detect the junction temperature. Hence, the detection accuracy of the junction temperature can be improved, and the junction temperature can be measured in real time without time delay.

Moreover, as the twisted design is applied to the temperature sensor 50A (i.e., which is achieved by turning twice), the resistance thereof can be large enough, thereby increasing a range of the voltage across two ends of the temperature sensor 50A under a condition of the constant current passing therethrough. Thus, the precision requirement of the voltage detecting circuit E can be reduced, thereby reducing the overall cost of measuring junction temperature. Furthermore, larger areas for detecting can be achieved by the twisted design, so the thermal equilibrium can get reached rapidly.

In addition, in some embodiments, the electrodes 202, 204, 302 and 304 and the extending portions 53, 57 of the temperature sensor 50A have the same material, such that they can be manufactured in the same process (i.e., which means they can be formed from the same layer). Thus, the semiconductor device 1A can be manufactured more efficiently.

On the other hand, in other embodiments, the electrodes 202, 204, 302 and 304 and the extending portions 53, 57 of the temperature sensor 50A can have different materials, and the extending portions 53, 57 of the temperature sensor 50A has a positive temperature coefficient greater than that of the electrodes 202, 204, 302 and 304; and therefore, the detection accuracy of the junction temperature can be further improved.

Furthermore, as shown in FIG. 1B, the extending portions 53, 57 of the temperature sensor 50A are spaced apart from each other by a distance DS1, and each of the electrodes 204, 302 of the nitride-based transistors 20, 30 is spaced apart from each of the extending portions 53,57 of the temperature sensor 50A by a distance DS2. The distance DS2 is greater than the distance DS1. Therefore, the parasite capacitance between the extending portion 53/57 and electrode 204/302 can be reduced, such that the negative impacts brought by the parasite capacitance on the nitride-based transistors 20, 30 can be alleviated.

The passivation layer 64 is disposed on/over/above the electrodes 202, 204, 302, 306, the passivation layer 40 and the temperature sensor 50. The passivation layer 64 covers the electrodes 202, 204, 302, 306, the passivation layer 40 and the temperature sensor 50A, such that the electrodes 202, 204, 302, 306 and the extending portions 53, 57 of the temperature sensor 50A are electrically isolated from each other.

Due to the configuration of the passivation layers 40 and 62, the temperature sensor 50A can be electrically independent of other elements in the semiconductor device 1A, which means the circuit of the temperature sensor 50A and the circuit of the nitride-based transistor 20/30 are independent from each other. As such, the voltage detecting circuit E can detect voltage across two ends of the temperature sensor 50A without affecting the operation of the semiconductor device 1A. That is to say, during the operation method of the semiconductor device 1A, the step of heating the nitride-based transistor 20 and the step of the collecting variety in a value of a voltage of the temperature sensor 50A can be executed at the same time period instead of using switches. Therefore, the complexity of the measuring circuit of the present disclosure can be reduced, and the error generated during the switching period can be reduced too.

The exemplary material of the passivation layer 64 can be identical with or similar with that of the passivation layer 40. Moreover, the passivation layer 64 can serve as a planarization layer which has a level top surface to support other layers/elements. In some embodiments, the passivation layer 64 can be formed as a thicker layer, and a planarization process, such as chemical mechanical polish (CMP) process, is performed on the passivation layer 64 to remove the excess portions, thereby forming a level top surface.

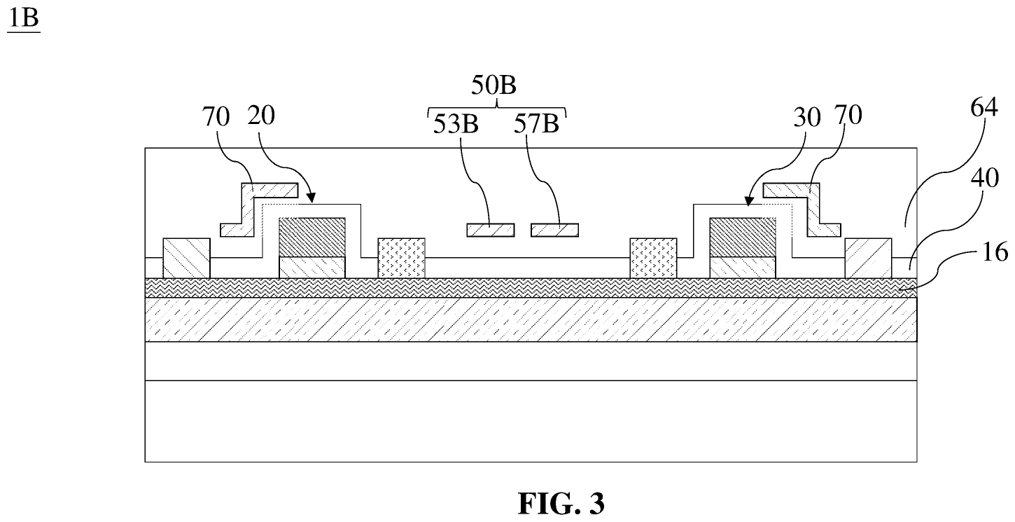

FIG. 3 is a vertical view of an enlarged region of a semiconductor device 1B according to some embodiments of the present disclosure. The semiconductor device 1B is similar to the semiconductor device 1A as described and illustrated with reference to FIGS. 1A,1B and 1C, except that the semiconductor device 1B further includes a field plate 70 to modulate electrical field distribution therein, and the temperature sensor 50A is replaced by the temperature sensor 50B. The field plate 70 and the temperature sensor 50B are disposed/embedded in the passivation layer 64. The temperature sensor 50B is spaced apart from the passivation layer 40. A portion of the field plate 70 overlaps with the nitride-based transistor 20, and another portion of the field plate 70 overlaps with the nitride-based transistor 30. A height of bottom portions of the field plate 70 with respect to the nitride-based semiconductor layer 16 can be the same as that of the temperature sensor 50B. In some embodiments, the bottom portions of the field plate 70 and the extending portions 53B, 57B of the temperature sensor 50B have the same material, such that they can be manufactured in a common process. Thus, the semiconductor device 1B can be manufactured more efficiently.

The exemplary materials of the field plate 70 can include, for example but are not limited to, conductive materials, such as Ti, Ta, TiN, TaN, or combinations thereof. In some embodiments, other conductive materials such as Al, Cu doped Si, and alloys including these materials may also be used.

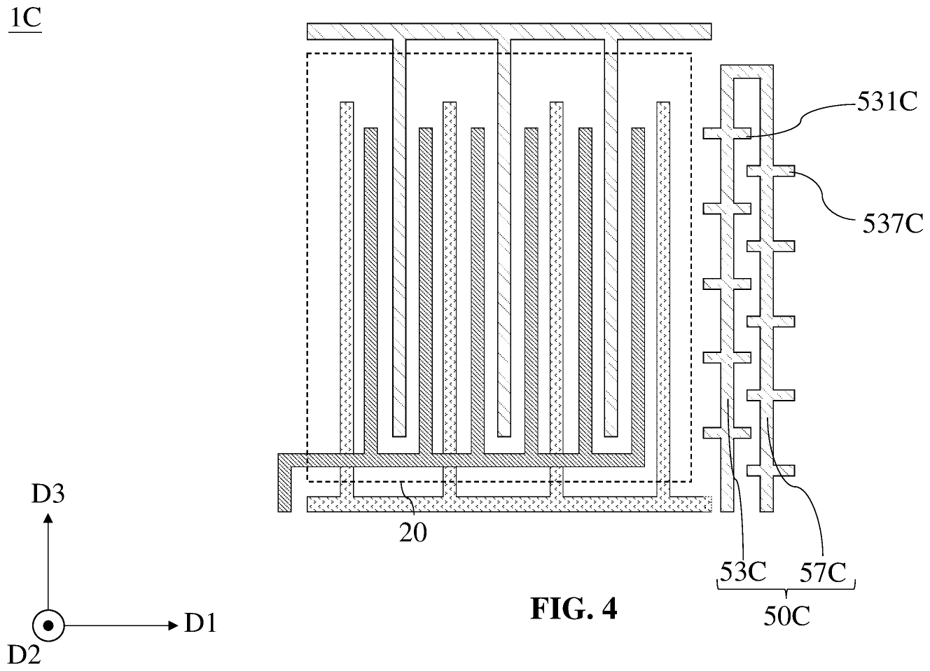

FIG. 4 is a top view of an enlarged region of a semiconductor device 1C according to some embodiments of the present disclosure. The semiconductor device 1C is similar to the semiconductor device 1A as described and illustrated with reference to FIGS. 1A,1B and 1C, except that the temperature sensor 50A is replaced by the temperature sensor 50C. At least one of the extending portions 53C, 57C of the temperature sensor 50C has a plurality of protruding portions. Specifically, in the embodiment, the extending portion 53C has a plurality of protruding portions 531C, and extending portion 53C has a plurality of protruding portions 537C. The extending direction of the protruding portions 531C and 537C can be different from that of the extending portions 53C and 57C. For example, the extending direction of the protruding portions 531C and 537C is the direction D1. In other embodiments, the extending direction of the protruding portions 531C and 537C can be a direction between the directions D1 and D3, and the disclosure is not limited thereto.

Due to the configuration of the protruding portion, the coverage area of the temperature sensor 50C in the semiconductor device 1C can be increased, and thus the temperature sensor 50C can feed back a more accurate temperature signal to the voltage detecting circuit E. Such the configuration is suitable for HEMT devices. The reason is more areas will usually bring the risk of parasitic capacitance raised, but HEMT devices is simpler than silicon devices (e.g., fewer metal layers) the weight for such the issues can be reduced.

Based on the above description, in embodiments of the present disclosure, the semiconductor device is integrated with a thermal resistor, such that the temperature sensor can sense the junction temperature of the semiconductor device accurately and immediately, thereby outputting a temperature signal according to the junction temperature. Thus, the accuracy of junction temperature measurement can be improved.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer and having a bandgap greater than a bandgap of the first nitride-based semiconductor layer, so as to generate a two-dimensional electron gas (2DEG) region adjacent to heterojunction between the first and second nitride-based semiconductor layers;
a first nitride-based transistor disposed over the second nitride-based semiconductor layer and applying the 2DEG region as an own channel;
a second nitride-based transistor disposed over the second nitride-based semiconductor layer and applying the 2DEG region as an own channel; and
a temperature sensor disposed over the second nitride-based semiconductor layer and between the first and second nitride-based transistors, wherein the temperature sensor is in a strip shape and at least turns twice in a region between first and second nitride-based transistors.

2. The nitride-based semiconductor device of claim 1, wherein the temperature sensor has a pair of extending portions parallel with each other and a connection portion connecting one of the extending portions to another one of the extending portions.

3. The nitride-based semiconductor device of claim 2, wherein the first nitride-based transistor comprises at least one source electrode and at least one drain electrode, and the extending portions extend along a length greater than a length of the source electrode and drain electrode.

4. The nitride-based semiconductor device of claim 1, wherein the temperature sensor is around a periphery region of the first nitride-based transistor.

5. The nitride-based semiconductor device of claim 1, further comprising:
a pair of conductive pads connected to two ends of the thermal resistor, respectively.

6. The nitride-based semiconductor device of claim 5, wherein each of the first and second nitride-based transistors has an active region, and the conductive pads viewed along a direction normal to the second nitride-based semiconductor layer are out of the active region in a top view.

7. The nitride-based semiconductor device of claim 1, wherein each of the first and second nitride-based transistors has an active region, and the temperature sensor viewed along a direction normal to the second nitride-based semiconductor layer is out of the active region in a top view.

8. The nitride-based semiconductor device of claim 1, further comprising:
a first passivation layer disposed on the second nitride-based semiconductor layer, wherein each of the first and second nitride-based transistors comprises a source electrode and a drain electrode penetrating the first passivation layer, and the temperature sensor is disposed on the first passivation layer.

9. The nitride-based semiconductor device of claim 8, further comprising:
a second passivation layer disposed on the first passivation layer and covering the source electrodes and drain electrodes and the thermal resistor.

10. The nitride-based semiconductor device of claim 1, wherein each of the first and second nitride-based transistors comprises a source electrode, the temperature sensor has a pair of extending portions parallel with each other and between the source electrodes of the first and second nitride-based transistors.

11. The nitride-based semiconductor device of claim 10, wherein the extending portions of the temperature sensor are spaced apart from each other by a first distance, and each of the source electrodes of the first and second nitride-based transistors is spaced apart from each of the extending portions of the temperature sensor by a second distance greater than the first distance.

12. The nitride-based semiconductor device of claim 10, wherein the source electrodes of the first and second nitride-based transistors and the extending portions of the temperature sensor have the same material.

13. The nitride-based semiconductor device of claim 10, wherein the source electrodes of the first and second nitride-based transistors and the extending portions of the temperature sensor have different materials, and the extending portions of the temperature sensor has a positive temperature coefficient greater than that of the source electrodes of the first and second nitride-based transistors.

14. The nitride-based semiconductor device of claim 10, wherein the source electrodes of the first and second nitride-based transistors and the extending portions of the temperature sensor are electrically isolated from each other.

15. The nitride-based semiconductor device of claim 1, further comprising:
a field plate overlapping with the first nitride-based transistor, wherein the field plate and the temperature sensor have the same material.

16. A method for operating a nitride-based semiconductor device, comprising:
switching on a nitride-based transistor in the nitride-based semiconductor device by inputting a first current into the nitride-based transistor;
inputting a second current into a temperature sensor in the nitride-based semiconductor device; and
collecting variety in a value of a first voltage of the temperature sensor during a time period of inputting the second current.

17. The method of claim 16, further comprising:
increasing a value of the first current; and
continuously collecting variety in the value of the first voltage in response to the increase of the value of the first current.

18. The method of claim 16, further comprising:
decreasing a value of the first current; and
continuously collecting variety in the value of the first voltage in response to the decrease of the value of the first current.

19. The method of claim 16, wherein inputting the second current is performed after switching on the nitride-based transistor.

20. The method of claim 16, wherein the nitride-based transistor and the temperature sensor are packaged such that the nitride-based transistor is adjacent to the thermal resistor.

21-25. (canceled)
